(19) United States
(12) Patent Application Publication
(10) Pub. No.: US 2009/0160518 A1
(43) Pub. Date: Jun. 25, 2009

(54) METHOD IMPLEMENTING PERIODIC BEHAVIORS USING A SINGLE REFERENCE

(75) Inventor: Mayan Moudgill, White Plains, NY (US)

Correspondence Address: BARNES & THORNBURG LLP, 750-17TH STREET NW, SUITE 900, WASHINGTON, DC, 20006-4675, US

(73) Assignee: Sandbridge Technologies, Inc., White Plains, NY (US)

(21) Appl. No.: 12/274,935

(22) Filed: Nov. 20, 2008

Related U.S. Application Data
(60) Provisional application No. 60/989,416, filed on Nov. 20, 2007.

(51) Int. Cl. H03K 5/13

(52) U.S. Cl. 327/231

(57) ABSTRACT

A method for processing information is described. The method includes providing a phase reference, Φᵢ, where the phase reference comprises N distinct values, expressed as Φᵢ=Φ₀ . . . Φ_{N-1}. A reset signal is received. The phase reference, Φ₀, is initialized in response to receipt of the reset signal. The phase reference values are repeatedly advanced from Φ₀ through Φ_{N-1}. The process then includes enabling at least one function at a predetermined phase reference value Φ_{A}, wherein Φ_{A}ε{Φ₀ . . . Φ_{N-1}}.

### CROSS-REFERENCE TO RELATED APPLICATIONS

This International Application relies for priority on U.S. Provisional Patent Application Ser. No. 60/989,416, which was filed on Nov. 20, 2007, the contents of which are incorporated herein by reference.

### FIELD OF THE INVENTION

This invention relates to signal processing by a processor. In particular, this invention concerns processing of signals implementing periodic behaviors using one reference.

### DESCRIPTION OF THE RELATED ART

In the prior art, when a hardware block is implemented after a reset, at cycle 4i+0, the hardware block drives a signal from a first register A. Then, at cycle 4i+2, the hardware drives the signal from a second register B. At all other times, the hardware drives the signal to 0.

As should be appreciated by those skilled in the art, this is an example of periodic behavior, with a period of 4 cycles. In other words, within each group of 4 cycles, the hardware block repeats the same behavior.

As may be appreciated by those skilled in the art, a standard way of implementing the processing in this 4-cycle hardware block is with an external control to drive the block. An example of the implementation of the standard approach is provided below in Code Segment #1.

Code Segment #1:

ENTITY example IS

PORT(

| | |
|---|---|
| en_A | : IN std_logic; |
| en_B | : IN std_logic; |
| val | : OUT std_logic_vector(15 DOWNTO 0); |
| ); | |

END ENTITY example;
ARCHITECTURE behavior OF example IS

CONSTANT A : std_logic_vector(15 DOWNTO 0) := ...;
CONSTANT B : std_logic_vector(15 DOWNTO 0) := ...;

BEGIN

val <=

| | |
|---|---|
| A | WHEN en_A = ‘1’ ELSE |
| B | WHEN en_B = ‘1’ ELSE |
| X“0000”; | |

END ARCHITECTURE behavior;

This implementation takes no advantage of the periodicity incorporated into the code segment. Code Segment #1 relies on externally generated control.

As a result, there has developed an interest in the art for implementations that do avail themselves of the periodicity incorporated into a particular code segment.

This need remains unaddressed by the prior art.

### SUMMARY OF THE INVENTION

The invention is directed to at least this failing in the prior art by implementing an instruction set that capitalizes on the periodicity incorporated into a particular code segment.

One aspect of the invention implements a hardware block in an environment that exhibits a periodic behavior with a period of N cycles. Within the N cycles, at various points, the hardware block executes functions that may differ from one another.

Contrary to the standard implementation technique, the invention provides “enables” for each of the separate executions of the functions within the hardware block with a period of N.

In one embodiment of the invention, the hardware block is implemented via a technique where a single reference is provided according to a 0 . . . N−1 count. All controls are generated locally based on that reference.

Other aspects of the invention will become apparent from the description that follows and the drawings appended hereto.

### BRIEF DESCRIPTION OF THE DRAWINGS

The invention will now be described in connection to the figures appended hereto, in which:

FIG. 1 is a table illustrating an offset function provided by one embodiment of the invention;

FIG. 2 is a table illustrating a phase shift function provided by another embodiment of the invention;

FIG. 3 is a flow chart detailing various processing steps provided by one or more embodiments of the invention;

FIG. 4 is a flow chart detailing an embodiment of the invention with respect to information processing;

FIG. 5 is a flow chart detailing a method for phase shifting or offsetting according to the invention; and

FIG. 6 is a flow chart detailing a different method for phase shifting or offsetting according to the invention.

### DESCRIPTION OF PREFERRED EMBODIMENTS OF THE INVENTION

In connection with the description of the invention, one or more embodiments are described. As should be appreciated by those skilled in the art, the embodiments are intended to be exemplary only. Those skilled in the art will readily appreciate that there are equivalents and variations that also may be implemented without departing from the scope of the invention. Those equivalents and variations are intended to fall within the scope of the invention as described herein.

As discussed above, in the prior art, when a hardware block is implemented after a reset, at cycle 4i+0, the hardware block drives a signal from a first register A. Then, at cycle 4i+2, the hardware drives the signal from a second register B. At all other times, the hardware drives the signal to 0. As noted above, a standard way of implementing the processing in this 4-cycle hardware block is with an external control to drive the block.

The invention avoids implementing the processing in this 4-cycle hardware block with an external control to drive the hardware block. The invention, at least in one or more of its embodiments, internalizes control into the hardware block, at least partially.

Specifically, the invention incorporates a counter that is the length of the period. In one contemplated embodiment, the counter operates from 0 . . . 3. In the generic embodiment, the counter operates from 0 . . . N−1. Relying on the counter, the hardware block implements its control based on the value of the period. An example of this implementation is provided by Code Segment #2, below.

Code Segment #2

ENTITY example IS

PORT(

| | |
|---|---|
| id | : IN std_logic_vector(1 DOWNTO 0); |
| val | : OUT std_logic_vector(15 DOWNTO 0); |
| ); | |

END ENTITY example;
ARCHITECTURE behavior OF example IS

CONSTANT A : std_logic_vector (15 DOWNTO 0) := ...;
CONSTANT B : std_logic_vector (15 DOWNTO 0) := ...;

BEGIN

WITH id SELECT

val <=

| | |
|---|---|
| A | WHEN “00”, |
| B | WHEN “11”, |
| X“0000” | WHEN “01” \| “10”, |
| (OTHERS => ‘X’) | WHEN OTHERS; |

END ARCHITECTURE behavior;

In this embodiment, external control is still required to generate an id counter so that 0 corresponds to the point at which A is read, and so on.

While acceptable, this approach is inconvenient for several reasons. For example, it is conceivable that there may be multiple blocks with the same period, but which need to initiate at different start times. As a result, a more efficient approach is to have only one counter feeding all of the blocks.

In addition, during development, it may be necessary to shift the start point of one or more of the blocks by one cycle.

In another contemplated variation, it may be necessary to move the example block by two cycles so that A is selected at 4i+2, and B at 4i+5=4*(i+1)+1.

Taking this into account, the invention contemplates an approach where the behaviors of one or more of the blocks are shifted by some offset from the counter 0. One straight forward way of doing this is by decrementing the counter by the offset. An example of this approach is provided in Code Segment #3, below.

Code Segment #3

ENTITY example IS

PORT(

| | |
|---|---|
| id | : IN std_logic_vector(1 DOWNTO 0); |
| val | : OUT std_logic_vector(15 DOWNTO 0); |
| ); | |

END ENTITY example;
ARCHITECTURE behavior OF example IS

CONSTANT offset : integer := 2;
CONSTANT A : std_logic_vector(15 DOWNTO 0) := ...;
CONSTANT B : std_logic_vector(15 DOWNTO 0) := ...;
SIGNAL id_adj : std_logic_vector(id′range);

BEGIN

id_adj <= std_logic_vector(

unsigned(id) − to_unsigned(i, offset));

WITH id_adj SELECT

val <=

| | |
|---|---|
| A | WHEN “00”, |
| B | WHEN “11”, |
| X“0000” | WHEN “01” \| “10”, |
| (OTHERS => ‘X’) | WHEN OTHERS; |

END ARCHITECTURE behavior;

As is apparent, in this approach, the 0 of the id is moved back to where the block expects it to be. Thus, if the id is 4i+2, id_adj will be 4i+0, and A will be selected.

An alternative to this approach is to move the phase in which the behavior will be selected. Thus, the code is changed so that A will now be triggered when id is 2 (i.e., “10”) instead of 0. This approach is detailed in Code Segment #4, below. For this approach, it is noted that VHSIC Hardware Description Language (“VHDL”) is not a valid variable. If VHDL were a valid variable, the example would be much larger, making awkward the illustration of this approach. For this reason, VHDL is presented in the manner provided in Code Segment #4.

Code Segment #4

ENTITY example IS

PORT(

| | |
|---|---|
| id | : IN std_logic_vector(1 DOWNTO 0); |
| val | : OUT std_logic_vector(15 DOWNTO 0); |
| ); | |

END ENTITY example;
ARCHITECTURE behavior OF example IS

CONSTANT offset : integer := 2;
CONSTANT uoff : unsigned := to_unsigned(offset, 2);
CONSTANT A : std_logic_vector(15 DOWNTO 0) := ...;
CONSTANT B : std_logic_vector(15 DOWNTO 0) := ...;
SIGNAL id_adj : std_logic_vector(id′range);

BEGIN

WITH id SELECT

val <=

| A | WHEN “00” + uoff, |
|---|---|
| B | WHEN “11” + uoff, |
| X“0000” | WHEN “01” + uoff \| “10” + |
| | uoff, |
| (OTHERS => ‘X’) | WHEN OTHERS; |

END ARCHITECTURE behavior;

The invention will now be described in connection with what is referred to as “state access.”

In one contemplated example of the invention, a state includes four (4) identical banks, A, B, C, and D. The banks are accessed periodically, with A, B, C, and D being read at phases 0, 1, 2, and 3 and being written at phase 3, 0, 1, and 2. This arrangement exists in a multi-threaded processor with 4 threads, where the threads are barrel-threaded (i.e., they are processed in a fixed sequence). In this example, the 4 banks correspond to the state of each of the threads, where the state for a thread t is read at 4i+t and written at 4i+t+3. A sample implementation for this example is provided below in Code Segment #5.

Code Segment #5

ARCHITECTURE behavior OF state IS

TYPE reg_type IS ARRAY(0 TO 3) OF

std_logic_vector(8 DOWNTO 0);

SIGNAL regs : reg_type;

BEGIN

th_gen: FOR i IN 0 TO 3 GENERATE

CONSTANT thid : std_logic_vector(1 DOWNTO 0) :=

std_logic_vector(to_unsigned(i+3 mod 4, 2));

SIGNAL en : std_logic;

BEGIN

en <= ‘1’ WHEN id = thid ELSE ‘0’;
regs(i) <= write_value WHEN rising_edge(clock)

and en = ‘1’;

END GENERATE th_gen;
read_val <= regs (to_integer(unsigned(id)));

END ARCHITECTURE behavior;

In the example provided in Code Segment #5, the phase of the counter is assumed to be in a condition such that phase 0 corresponds to the read of thread 0.

Suppose the phase of the counter changes so that the phase 0 of the counter is moved by one cycle, so that the phase corresponds to a read of thread 1. In this particular instance, the logic set forth above does not change. Instead, the state for thread 1 will be stored in regs(0), and so on, with the state for thread 0 being stored in regs(3). The function, however, remains the same.

As should be appreciated by those skilled in the art, the embodiments discussed so far have focused on loops comprising 4 steps, enabled at counters 0, 1, 2, and 3, in the simplest example. The invention, however, is not limited to four steps, but may encompass N steps. When N steps are incorporated into the loop, the counter will enable the functions from 0 to N−1. As also may be appreciated by those skilled in the art, the loop will contain at least two functions because one aspect of the invention is to capitalize on the periodicity of certain processing schema.

Taking this into account, a loop may contain N steps with at least a first function and a second function being enabled at steps X and Y respectively within the loop. Steps other than the first and second functions drive the signal to 0.

As is apparent from the foregoing, the start of one or more of the periods for a processing scheme may be shifted by one or more counts of the counter. In other words, the start of the period is altered to begin at a different cycle within the loop. This is referred to as an offset.

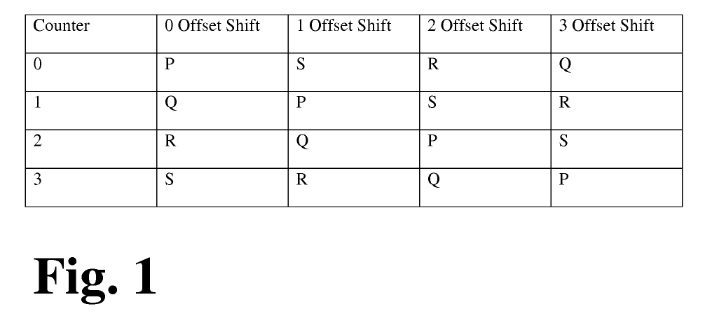

FIG. 1 provides a visual illustration of several offsets for a single processing period. In FIG. 1, the counter increments from 0 to 3. In FIG. 1, there are four process steps P, Q, R, and S. If an offset of 1 is employed, then the four process steps initiate at counter 1. The four steps P, Q, R, and S then proceed, in order, until complete. If the offset is greater than 1, the four process steps are incremented a greater amount, as illustrated. As should be appreciated by those skilled in the art, the offset may be greater if N>4.

In cases where several hardware blocks assist with the processing scheme, the counter applies to each of the hardware blocks. In addition, one or more of the hardware blocks may be offset from others of the hardware blocks.

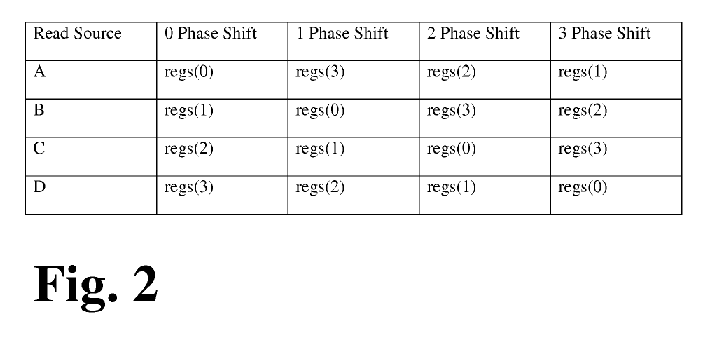

FIG. 2 illustrates phase shifting. In this illustration, the read source lists the different banks A, B, C, and D that are accessed by the periodic processing function. When processing hardware blocks A, B, C, and D, data processed from block A is written to the lowest numbered registers, which are regs(0). Accordingly, data processed from block B is written to regs(1), block C to regs(2) and block D to regs(3).

However, the hardware blocks need not write to these registers. Instead, they may be shifted out of phase from the default condition. For example, in a phase shift where the shift amount S=1, data processed from block B is written to regs(0), block C to regs(1), block D to regs(2) and block A to regs (3). The phase shift may be more than 1, as should be appreciated by those skilled in the art.

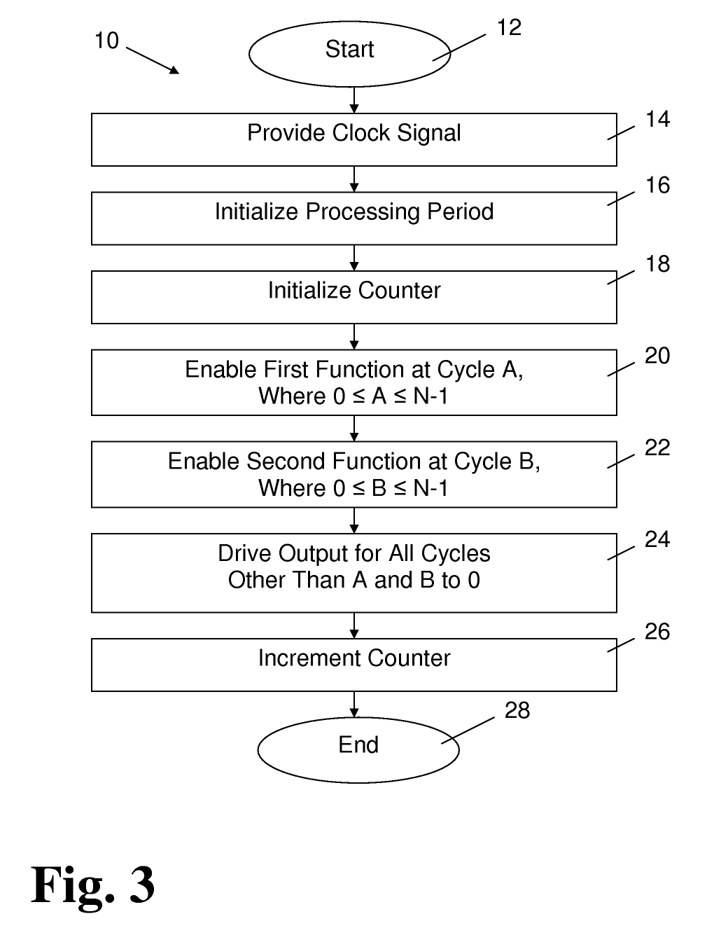

With reference to FIG. 3, one process 10 provided by the invention starts at 12. The process then proceeds to 14 where a clock signal is provided. The process proceeds to 16 where the processing period is initialized. Then, at 18, the counter is initialized. Following this, at 20, a first function is enabled at cycle A, where 0≦A≦N−1. At 22, a second function is enabled at cycle B, where 0≦B≦N−1. At 24, for all other cycles other than A and B, the output signal is driven to 0. At 26, the counter is incremented. At 28, the process ends.

In the discussion above, the id counter is viewed as providing a N-valued phase reference Φᵢ. As is apparent from the foregoing discussion, 0 to N−1 have been used herein to identify phase reference values, but any sequence of N distinct values within the range Φ₀ . . . Φ_{N-1} may be used without departing from the scope of the invention. In one contemplated embodiment, a grey-counter (values 00, 01, 10, 11) may be employed to provide the phase reference values.

As should be apparent, different behaviors in the block are triggered when the phase reference reaches a particular predetermined value. From a generic perspective, function A is enabled when the phase reference value is Φ_{A}. As may be appreciated by those skilled in the art, Φ_{A}ε{Φ₀ . . . Φ_{N-1}}. Accordingly, function A is triggered at a predetermined phase reference point within the total phase range.

Separately, it is contemplated that the same function may be enabled more than once during the processing period. For example, function A may be enabled at phase reference values, Φ_{A1} and Φ_{A2}. It should be apparent to those skilled in the art that Φ_{A1}ε{Φ₀ . . . Φ_{N-1}} and that Φ_{A2}ε{Φ₀ . . . Φ_{N-1}} In most cases, it is contemplated that the total phase range corresponds to a single processing period. As should be apparent, the phase range alternatively may correspond to more than one processing period without departing from the invention.

Not only may the same function be repeated during a processing period, it is also contemplated that a plurality of functions, X . . . Y, may be processed at different predetermined phase reference values, Φ_{A}.

Additionally, the invention contemplates using an offset δ. Use of an offset δ within a block is equivalent to moving the enable point (Φ_{A}) of the function A by δ with respect to the phase reference. The value of the offset δ equates with a displacement with respect to the original phase. This may be implemented in one of two ways:

(1) A second phase reference sequence may be generated by rotating the original phase reference sequence by δ, so that Φ′ᵢ=Φ_{(i+δ) mod N}; or

(2) The enable point may be moved by δ, so that the function A is enabled when the phase reference value is Φ′_{A}=Φ_{(A-δ) mod N}.

Other offsets may be employed as well, these two examples merely being illustrative of two approaches contemplated by the invention.

In some blocks, such as the register example above, the absolute position of a behavior with respect to the phase reference is not determinative. Instead, there may be two (or more) behaviors, and it is the phase difference or distance between them that is determinative. Thus, in the register example above, the invariant that Φ_{read}=Φ_{(write+1) mod N} is maintained. Such blocks are immune to changes in the origin of the phase reference.

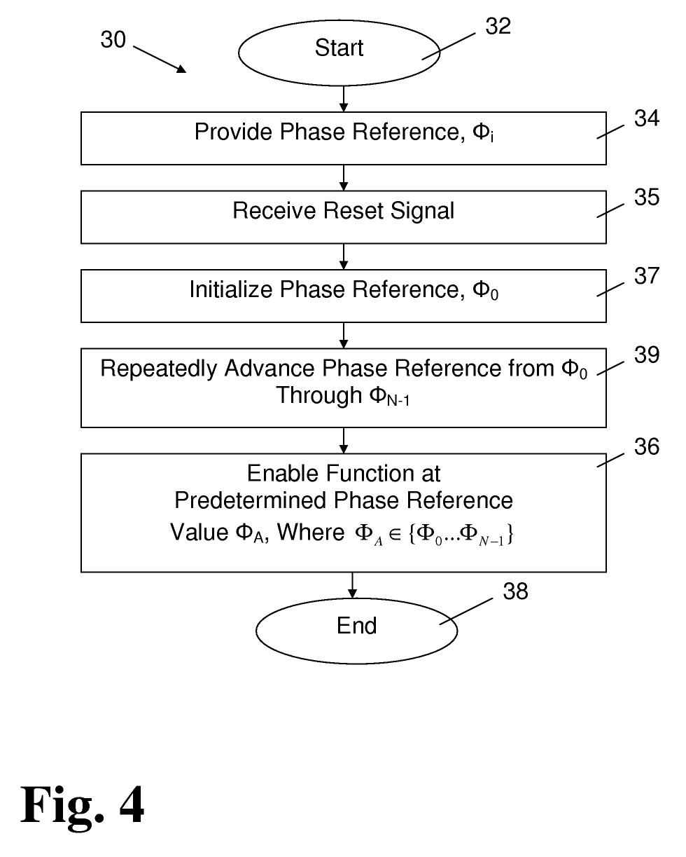

Reference is now made to FIG. 4, which provides a flow diagram for a contemplated embodiment of the invention. A method 30 is provided for processing information. The method 30 starts at 32. The method 30 then proceeds to 34 where a phase reference, Φᵢ, is provided. The phase reference has N distinct values, expressed as Φᵢ=Φ₀ . . . Φ_{N-1}. A reset signal is received at 35. The phase reference, Φ₀, is then initialized at 37 in response to the reset signal. At 39, the phase reference values are then repeatedly advanced from to Φ₀ through Φ_{N-1}. At 36, a function is then enabled at a predetermined phase reference value Φ_{A}, where Φ_{A}ε{Φ₀ . . . Φ_{N-1}}. The process 30 ends at 38.

In one contemplated variation of the method 30, the phase reference is sequentially incremented by a counter from 0 to N−1, thereby defining at least one processing period. In another contemplated variation, the method 30 includes receiving a reset signal. Upon receipt of the reset signal, the phase reference is initialized to 0. In still another variation of the method 30, a clock signal is received. The phase reference phase reference, Φᵢ, is incremented in response to receipt of the clock signal.

As may be appreciated from the foregoing, while the method 30 may be employed for a single function, it may alternatively be employed for multiple functions. In such a case, the plurality of functions may be enabled at different ones of the plurality of the predetermined phase reference values Φ_{A}.

In still another contemplated variation, one or more of the functions may be enabled multiple times during the processing period. If implemented, the function or functions may be enabled at two or more of the predetermined phase reference values Φ_{A}.

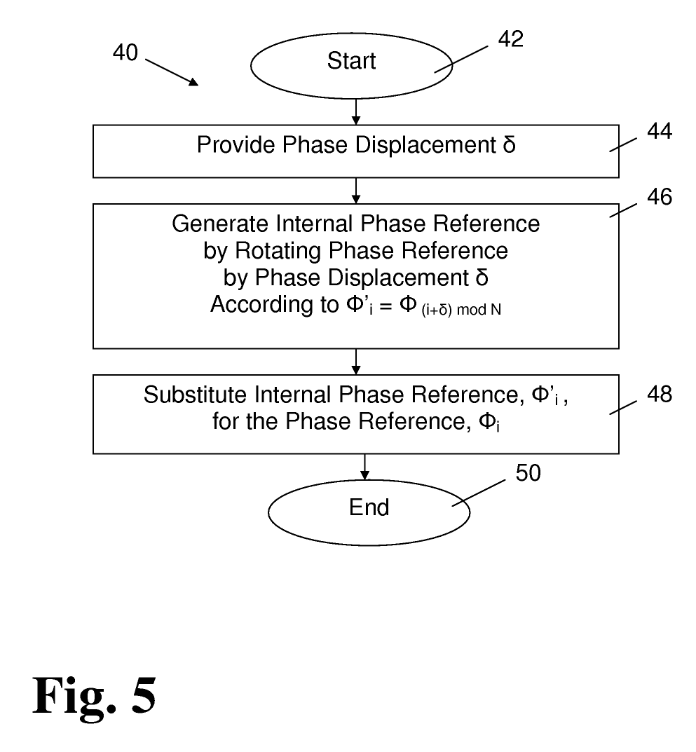

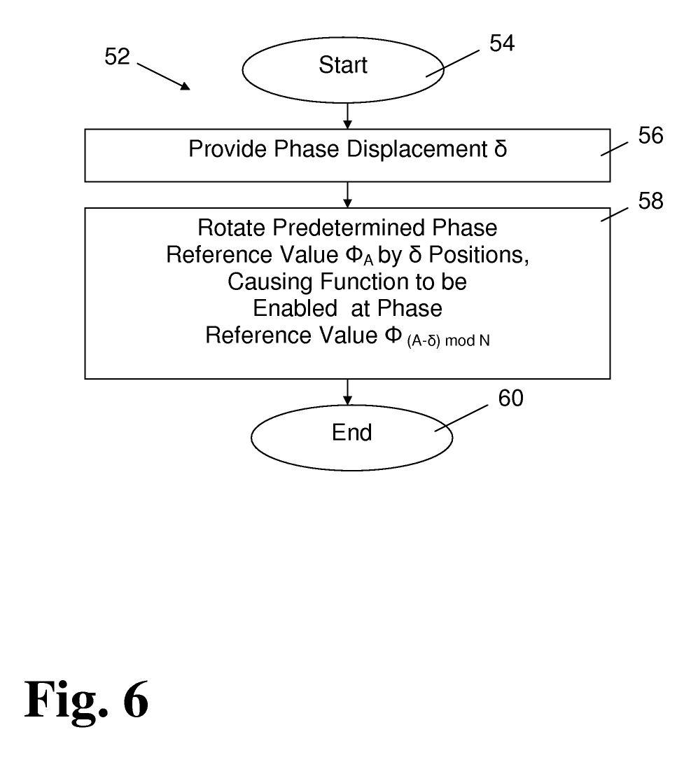

The invention also contemplates phase shifting. FIGS. 5 and 6 provide flow diagrams of at least two phase adjustments that are contemplated.

With reference to FIG. 5, one of the phase adjustments 40 is detailed. The method 40 begins at 42. At 44, a phase displacement 6 is provided. Then, at 46, an internal phase reference is generated by rotating the phase reference by the phase displacement δ according to the operation Φ′ᵢ=Φ_{(i+δ) mod N}. Here, the internal phase reference comprises N distinct values from 0 to N−1, expressed as Φ′ᵢ=Φ_{(i+δ) mod 0} . . . Φ′ᵢ=Φ_{(i+δ) mod N-1}. At 48, the internal phase reference, Φ′ᵢ is substituted for the phase reference, Φᵢ. The method 40 ends at 50.

As is apparent from the foregoing, once the internal phase reference, Φ′ᵢ is substituted for the phase reference, Φᵢ the method 30, illustrated in FIG. 4, then proceeds in a phase-shifted fashion. In other words, the function or functions are enabled at phase reference values Φ_{A}=Φ′ᵢ. As a result, the function or functions are then executed at different reference values from the reference values provided for by the method 30. This same approach may be applied in the case where several functions are executed during the processing period so that all of the functions are executed at phase-shifted reference values.

An alternative phase shift is illustrated in FIG. 6 by the method 52. The method 52 starts at 54. The method 52 then proceeds to 56 where a phase displacement 6 is provided. The method 52 then proceeds to 58, where the predetermined phase reference value Φ_{A} is rotated by δ positions, thereby causing the function to be enabled at phase reference value Φ_{(A-δ) mod N}. The method ends at 60. As with the method 40, the method 52 may be applied to a plurality of functions within the processing period or periods.

As should be appreciated by those skilled in the art, when various aspects of the invention are practiced, they may be employed during a single processing period. Alternatively, the various methods may be enabled on more than one processing period executed sequentially or in parallel. When executed in parallel, the processing periods may be executed on several separate hardware blocks at the same time.

When multiple hardware blocks process information at the same time, it is contemplated that not all of the processing blocks will operate in the same fashion. For example, in one contemplated embodiment, one or more of the processing blocks may operate without a phase change or offset while others of the hardware blocks may enable functions in a phase-shifted or offset manner. The phase shifts may be enabled according to one or both of methods 40 and 52. As should be apparent, in yet another variation, some of the hardware blocks may employ the method 40, while others employ the method 52.

As discussed above with reference to the method 10 illustrated in FIG. 3, processing in one of the plurality of hardware blocks may be augmented by shifting a start of the counter by a factor y such that the counter starts at 0+y. In this instance, each of the N cycles are enabled from counter 0+y to N−1, followed by enabling each of the cycles from 0 to 0+y−1. If this technique is employed for several of the hardware blocks, the start of the counter is shifted by a different factor such that each of the plurality of separate hardware blocks starts at a different cycle. While noted above, the functions may be any type of function including read and write functions. The read and write functions may access a data storage device or may operate only in active memory within a particular processor or group of processors.

When separate hardware blocks are employed, they may be numbered 0 through N. If so, they may include write functions that write to regs(0) through regs(N), respectively. When shifted, the separate hardware blocks operate according to a shift by S such that the write function writes to regs(0−S) though regs(N−S), where regs(0−S) correspond to regs(N−S+1) through regs(N), respectively.

As should be appreciated by those skilled in the art, there are numerous equivalents and variations of the embodiments described herein in connection with the invention. The equivalents and variations are intended to be encompassed by the invention.

What is claimed is:

1. A method for processing information, comprising:
providing a phase reference, Φᵢ, wherein the phase reference comprises N distinct values, expressed as Φᵢ=Φ₀ . . . Φ_{N-1};
receiving a reset signal;
initializing the phase reference, Φ₀, in response to receipt of the reset signal;
repeatedly advancing the phase reference values from to Φ₀ through Φ_{N-1}; and
enabling at least one function at a predetermined phase reference value Φ_{A}, wherein Φ_{A}ε{Φ₀ . . . Φ_{N-1}}.

2. The method of claim 1, wherein the phase reference, Φᵢ, is sequentially incremented by a counter from 0 to N−1, thereby defining at least one processing period.

3. The method of claim 2, wherein the phase reference, Φ₀, is initialized to 0 in response to receipt of the reset signal.

4. The method of claim 1, further comprising:
receiving a clock signal; and
incrementing the phase reference, Φᵢ, in response to receipt of the clock signal.

5. The method of claim 1, wherein the at least one function comprises a plurality of functions that are enabled at different ones of a plurality of the predetermined phase reference values Φ_{A}.

6. The method of claim 1, wherein the at least one function is enabled for at least two different predetermined phase reference values Φ_{A}.

7. The method of claim 1, further comprising:
providing a phase displacement δ;
generating an internal phase reference by rotating the phase reference by the phase displacement δ according to the operation Φ′ᵢ=Φ_{(i+δ) mod N}, wherein the internal phase reference comprises N distinct values from 0 to N−1, expressed as Φ′ᵢ=Φ_{(i+δ) mod 0} . . . Φ′ᵢ=Φ_{(i+δ) mod N-1}; and
substituting the internal phase reference, Φ′ᵢ, for the phase reference, Φᵢ.

8. The method of claim 5, further comprising:
providing a phase displacement δ;
generating an internal phase reference by rotating the phase reference by the phase displacement δ according to the operation Φ′ᵢ=Φ_{(i+δ) mod N}, wherein the internal phase reference comprises N distinct values from 0 to N−1, expressed as Φ′ᵢ=Φ_{(i+δ) mod 0} . . . Φ′ᵢ=Φ_{(i+δ) mod N-1}; and
substituting the internal phase reference, Φ′ᵢ, for the phase reference, Φᵢ.

9. The method of claim 1, further comprising
providing a phase displacement δ; and
rotating the predetermined phase reference value Φ_{A} by δ positions, thereby causing the at least one function to be enabled at phase reference value Φ_{(A-δ) mod N}.

10. The method of claim 5, further comprising
providing a phase displacement δ;
modifying the predetermined phase reference value Φ_{A} by δ positions, thereby causing the plurality of functions to be enabled at the predetermined phase reference values Φ_{(Ai-δ) mod N}.

11. The method of claim 2, wherein the at least one processing period comprises a plurality of processing periods executed on a plurality separate hardware blocks.

12. The method of claim 11, wherein the plurality of processing periods are executed on the plurality of separate hardware blocks in parallel with one another.

13. The method of claim 12, wherein, for at least one of the plurality of separate hardware blocks, the method further comprises:
providing a phase displacement δ;
generating an internal phase reference by rotating the phase reference by the phase displacement δ according to the operation Φ′ᵢ=Φ_{(i+δ) mod N}, wherein the internal phase reference comprises N distinct values from 0 to N−1, expressed as Φ′ᵢ=Φ_{(i+δ) mod 0} . . . Φ′ᵢ=Φ_{(i+δ) mod N-1}; and
substituting the internal phase reference, Φ′ᵢ, for the phase reference.

14. The method of claim 12, wherein, for at least one of the plurality of separate hardware blocks, the method further comprises:
providing a phase displacement δ;
generating an internal phase reference by rotating the phase reference by the phase displacement δ according to the operation Φ′ᵢ=Φ_{(i+δ) mod N}, wherein the internal phase reference comprises N distinct values from 0 to N−1, expressed as Φ′ᵢ=Φ_{(i+δ) mod 0} . . . Φ′ᵢ=Φ_{(i+δ) mod N-1}; and
substituting the internal phase reference, Φ′ᵢ, for the phase reference, Φᵢ,
wherein the at least one function comprises a plurality of functions that are enabled at different ones of a plurality of the predetermined phase reference values Φ_{A}.

15. The method of claim 11, wherein, for at least one other of the plurality of processing blocks, the method further comprises:
shifting a start of the counter by a factor y such that the counter starts at 0+y; and
enabling each of the N cycles from counter 0+y to N−1 followed by enabling each of the cycles from 0 to 0+y−1.

16. The method of claim 15, wherein, for each of the plurality of processing blocks, the start of the counter is shifted by a different factor such that each of the plurality of separate hardware blocks starts at a different cycle.

17. The method of claim 16, wherein the first function is a read function and the second function is a write function.

18. The method of claim 17, wherein each of the plurality of separate hardware blocks are numbered 0 through N, and the write function writes to regs(0) through regs(N), respectively.

19. The method of claim 18, wherein the phase of the plurality of separate hardware blocks is shifted by S such that the write function writes to regs(0−S) though regs(N−S), where regs(0−S) correspond to regs(N−S+1) through regs(N), respectively.
